(19) United States
(12) Patent Application Publication
(10) Pub. No.: US 2026/0089883 A1
(43) Pub. Date: Mar. 26, 2026

(54) COOLANT DISTRIBUTION UNIT

(71) Applicant: NIDEC CORPORATION, Kyoto (JP)

(72) Inventors: Toshihiko TOKESHI, Kyoto (JP); Taku MURAKAMI, Kyoto (JP)

(21) Appl. No.: 19/335,660

(22) Filed: Sep. 22, 2025

Related U.S. Application Data
(60) Provisional application No. 63/698,830, filed on Sep. 25, 2024.

(30) Foreign Application Priority Data
Nov. 8, 2024 (JP) 2024-196069

(51) Int. Cl. H05K 7/20

(52) U.S. Cl. CPC H05K 7/20272

(57) ABSTRACT

A coolant distribution unit includes a housing, a primary flow path, a secondary flow path, a heat exchanger, and an emission path. The primary flow path is housed in the housing and connects a primary inlet and a primary outlet provided in the housing. The secondary flow path is housed in the housing and connects a secondary inlet and a secondary outlet provided in the housing. The heat exchanger is housed in the housing and connected to the primary flow path and the secondary flow path. The emission path is housed in the housing and connects an emission port provided in the housing and the primary flow path or the secondary flow path.

### CROSS-REFERENCE TO RELATED APPLICATIONS

This application is a Non-Provisional Application of U.S. Provisional Application No. 63/698,830, filed on Sep. 25, 2024, and claims priority under 35 U.S.C. § 119 to Japanese Patent Application No. 2024-196069, filed on Nov. 8, 2024. The entire contents of the above-identified applications are hereby incorporated by reference.

### 1. FIELD OF THE INVENTION

The present disclosure relates to coolant distribution units.

### 2. BACKGROUND

In the related art, a coolant distribution unit is known that cools a heat source such as a central processing unit (CPU) by transferring heat from the heat source to a circulating coolant.

The coolant distribution unit in the related art includes, inside the unit, a flow path for primary cooling water and a flow path for secondary cooling water. An inlet and an outlet for the primary cooling water and an inlet and an outlet for the secondary cooling water are provided in a rear surface of the coolant distribution unit.

In this type of coolant distribution unit, pipes connected to the inlet and the outlet may be fixed by a clamp or the like. However, in such a case, when the clamp is removed and the pipe is detached from the inlet or the outlet, the coolant such as external cooling water or internal cooling water in the flow path may leak out of the coolant distribution unit from the inlet or the outlet.

Therefore, there is a demand for a coolant distribution unit that overcomes the above-described problems and suppresses leakage of the coolant from the inlet or the outlet to the outside of the unit when the pipe is detached.

### SUMMARY

A coolant distribution unit according to an example embodiment of the present disclosure includes a housing, a primary flow path, a secondary flow path, a heat exchanger, and an emission path. The primary flow path is housed in the housing and connects a primary inlet and a primary outlet which are provided in the housing. The secondary flow path is housed in the housing and connects a secondary inlet and a secondary outlet which are provided in the housing. The heat exchanger is housed in the housing and connected to the primary flow path and the secondary flow path. The emission path is housed in the housing and connects an emission port provided in the housing and the primary flow path or the secondary flow path.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic perspective view of a coolant distribution unit (CDU) according to an example embodiment of the present disclosure.

FIG. 2 is a schematic perspective view illustrating the interior of a CDU according to an example embodiment of the present disclosure.

FIG. 3 is a diagram illustrating a simplified configuration of a CDU according to an example embodiment of the present disclosure.

FIG. 4 is a schematic rear view of a CDU according to an example embodiment of the present disclosure.

FIG. 5 is a perspective view illustrating a rear surface of the CDU according to an example embodiment of the present disclosure.

FIG. 6 is a perspective view illustrating a rear surface of a CDU according to an example embodiment of the present disclosure.

FIG. 7 is a diagram illustrating a simplified configuration of a CDU according to a first variation of an example embodiment of the present disclosure.

FIG. 8 is a diagram illustrating a simplified configuration of a CDU according to a second variation of an example embodiment of the present disclosure.

FIG. 9 is a schematic rear view of a CDU according to a third variation of an example embodiment of the present disclosure.

### DETAILED DESCRIPTION

Hereinafter, coolant distribution units according to example embodiments of the present disclosure (hereinafter, referred to as “example embodiments”) will be described in detail with reference to the drawings. The present disclosure is not limited by the example embodiments. The example embodiments may be combined as appropriate without conflict between processing contents. In the following example embodiments, the same components are denoted by the same e reference numerals, and redundant description is omitted.

In addition, in each of the drawings referred in the following description, to make the description easy to understand, an orthogonal coordinate system may be illustrated in which an X-axis direction, a Y-axis direction, and a Z-axis direction orthogonal to or substantially orthogonal to each other are defined and the positive direction of the Z-axis is a vertically upward direction.

### Example Embodiments

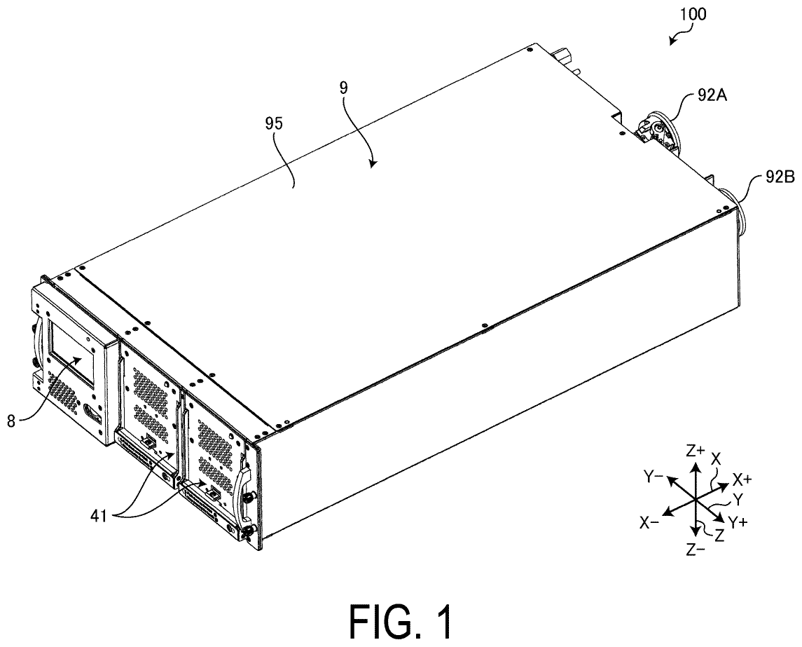

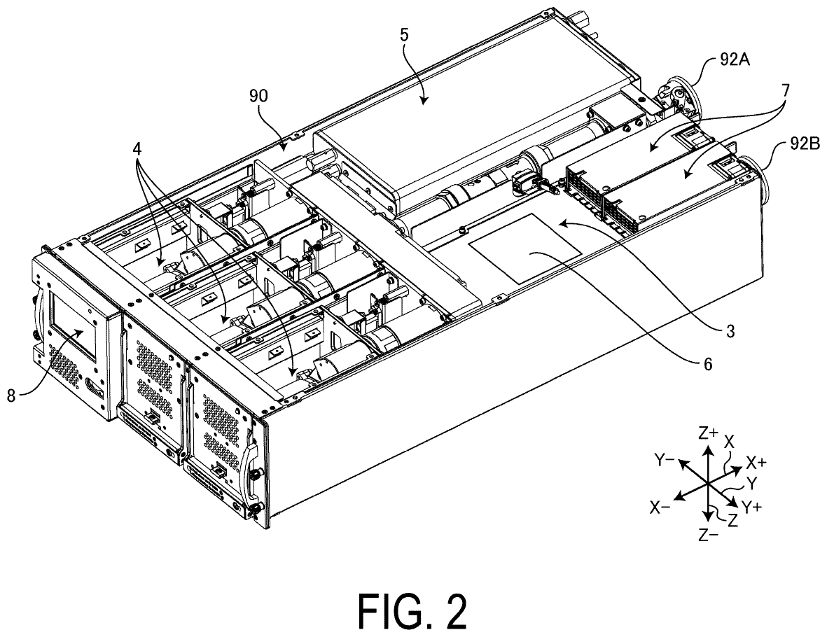

First, a configuration of a CDU 100 according to an example embodiment will be described with reference to FIGS. 1 and 2. FIG. 1 is a schematic perspective view of the CDU 100 according to the example embodiment. FIG. 2 is a schematic perspective view illustrating the interior of the CDU 100 according to the example embodiment. “CDU” is an abbreviation for “Coolant Distribution Unit”. The CDU 100 is an example of a coolant distribution unit.

The CDU 100 controls the flow rate, temperature, water quality, or water distribution destination of a coolant supplied from a facility side. The CDU 100 draws a primary coolant into the CDU 100 and pumps the primary coolant to the outside of the CDU 100. The CDU 100 draws a secondary coolant into the CDU 100 and pumps the secondary coolant to the outside of the CDU 100. A pump for the primary coolant is not provided inside the CDU 100, and thus suction and expulsion of the primary coolant for the CDU 100 are performed by an external pump.

The CDU 100 exchanges heat between the primary coolant and the secondary coolant. For example, a coolant such as an antifreeze solution or pure water can be used as the primary coolant and the secondary coolant. Examples of the antifreeze solution usable as the coolant include an ethylene glycol aqueous solution and a propylene glycol aqueous solution. The same type of coolant or different types of coolants may be used as the primary coolant and the secondary coolant. At least one of the primary coolant or the secondary coolant may be a gas coolant.

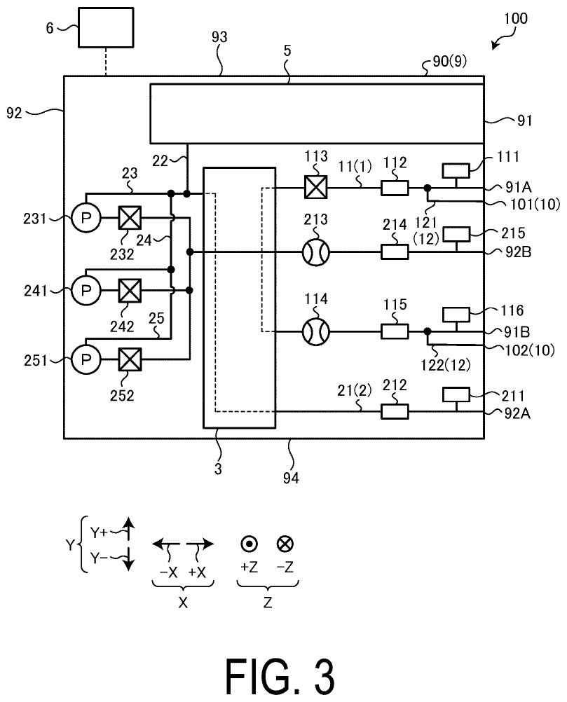

The CDU 100 includes a primary flow path 1 (see FIG. 3), a secondary flow path 2 (see FIG. 3), a heat exchanger 3, a pump unit 4, a tank 5, a control unit 6, a display operation unit 8, and a housing 9. The primary coolant flows through the primary flow path 1. The secondary coolant flows through the secondary flow path 2.

The heat exchanger 3 is connected to the primary flow path 1 and the secondary flow path 2. The primary coolant and the secondary coolant flow to the inside of the heat exchanger 3 and flow out from the inside of the heat exchanger 3. Inside the heat exchanger 3, heat exchange between the primary coolant and the secondary coolant is performed. The heat exchanger 3 is a plate heat exchanger, for example.

The pump unit 4 is connected to the secondary flow path 2. The pump unit 4 includes an internal flow path. When the pump unit 4 is driven, the secondary coolant is drawn into the internal flow path of the pump unit 4, and the secondary coolant is pumped from the internal flow path of the pump unit 4. This allows the secondary coolant to circulate between the CDU 100 and an external cold plate. The number of the pump units 4 installed is not particularly limited. For example, the number of the pump units 4 installed is three. That is, the CDU 100 includes a plurality of the pump units 4.

The tank 5 stores a coolant used as the secondary coolant. The tank 5 is connected to the secondary flow path 2. The tank 5 can supply the coolant to the secondary flow path 2.

The CDU 100 includes the control unit 6. The control unit 6 is connected to sensors such as a temperature and humidity sensor, temperature sensors for the primary coolant 112 and 115 (see FIG. 3), temperature sensors for the secondary coolant 212 and 214, a flow rate sensor on the primary coolant side 114, and pressure sensors on the secondary coolant side 211 and 215, which are disposed in the CDU 100. The control unit 6 controls the pump unit 4 and a valve 113.

The CDU 100 includes the display operation unit 8. The display operation unit 8 is provided on the front face of the CDU 100, and displays the operating status of the system, measured values of the sensors, and the like. The display operation unit 8 is, for example, a touch panel display.

The CDU 100 includes the housing 9. The housing 9 includes a containment region 90. The primary flow path 1, the secondary flow path 2, the heat exchanger 3, the pump unit 4, the tank 5, the control unit 6, and the display operation unit 8 are housed in the containment region 90 of the housing 9.

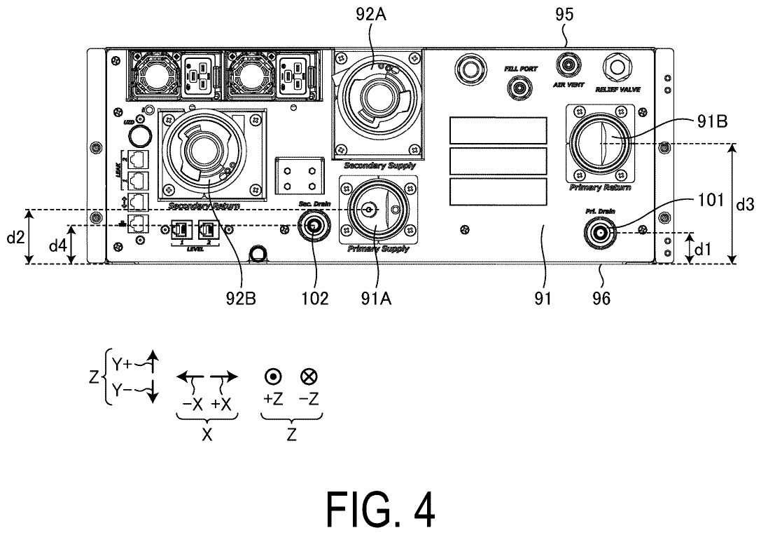

Next, the housing 9 of the CDU 100 according to the example embodiment will be described with reference to FIGS. 3 and 4. FIG. 3 is a diagram illustrating a simplified configuration of the CDU 100 according to the example embodiment. FIG. 4 is a schematic rear view of the CDU 100 according to the example embodiment.

The containment region 90 has a substantially rectangular shape in a plan view as viewed from the Z-axis direction, and the longitudinal direction of the rectangular shape is along the X-axis direction, and the transverse direction of the rectangular shape is along the Y-axis direction. That is, the containment region 90 extends in the X-axis direction and the Y-axis direction intersecting each other, and has a dimension in the X-axis direction longer than a dimension in the Y-axis direction. A depth direction of the containment region 90 is along the Z-axis direction. The width (depth) of the containment region 90 in the Z-axis direction is smaller than the widths of the containment region 90 in the X-axis direction and the Y-axis direction.

The housing 9 has a plurality of faces 91 to 96. The plurality of faces 91 to 96 surround the containment region 90. That is, the housing 9 includes a region surrounded by the plurality of faces 91 to 96 as the containment region 90.

The face 91 and the face 92 are disposed to face each other in the X-axis direction with the containment region 90 interposed therebetween. The face 91 is disposed on one side in the X-axis direction (the positive side in the X-axis direction). The face 92 is disposed on the other side in the X-axis direction (the negative side in the X-axis direction). In the following description, the face 91 may be referred to as a rear surface 91 to distinguish the face 91 from the other faces of the housing 9.

The face 93 and the face 94 are disposed to face each other in the Y-axis direction with the containment region 90 interposed therebetween. The face 93 is disposed on one side in the Y-axis direction (the positive side in the Y-axis direction). The face 94 is disposed on the other side in the Y-axis direction (the negative side in the Y-axis direction).

The face 95 and the face 96 are disposed to face each other in the Z-axis direction with the containment region 90 interposed therebetween. The face 95 is disposed on one side in the Z-axis direction (the positive side in the Z-axis direction). The face 96 is disposed on the other side in the Z-axis direction (the negative side in the Z-axis direction). In the following description, the face 96 may be referred to as a bottom face 96.

The face 96 is an example of a first surface located vertically below the heat exchanger 3, and the face 95 is an example of a second surface located opposite to the first surface. The faces 91 to 94 are an example of a plurality of third surfaces connecting the first surface and the second surface.

Next, the primary flow path 1 and the secondary flow path 2 according to the example embodiment will be described with reference to FIGS. 3 and 4. Note that FIG. 3 is a diagram schematically illustrating the primary flow path 1 and the secondary flow path 2 of the CDU 100, and arrangement of the members, for example, a primary inlet 91A, a primary outlet 91B, a secondary inlet 92A, a secondary outlet 92B, and an emission port 10 is not limited to the arrangement illustrated in FIG. 3.

The primary flow path 1 is a flow path connecting the primary inlet 91A and the primary outlet 91B provided in the housing 9. The primary inlet 91A and the primary outlet 91B are open in the rear surface 91 of the housing 9.

The primary flow path 1 includes a main flow path 11. The primary coolant flowing in from the primary inlet 91A passes through the main flow path 11 and flows out from the primary outlet 91B.

The main flow path 11 extends through the heat exchanger 3 and connects the primary inlet 91A and the primary outlet 91B. In the main flow path 11, a pressure sensor 111, the temperature sensor 112, the valve 113, the heat exchanger 3, the flow rate sensor 114, the temperature sensor 115, and the pressure sensor 116 are provided in order from the upstream side.

The pressure sensor 111 measures the pressure of the primary coolant flowing through the upstream part of the primary flow path 1, specifically, through a part of the primary flow path 1 upstream of the heat exchanger 3. The temperature sensor 112 is provided downstream of the pressure sensor 111 in the main flow path 11, and measures the temperature of the primary coolant flowing through the upstream part of the primary flow path 1. The valve 113 is provided downstream of the temperature sensor 112 in the main flow path 11, and controls the flow rate of the primary coolant flowing through the primary flow path 1. The valve 113 is, for example, an electromagnetic two-way valve, and the opening of the valve 113 can be adjusted by the control unit 6.

The heat exchanger 3 is provided downstream of the valve 113 in the main flow path 11.

The flow rate sensor 114 is provided downstream of the heat exchanger 3 in the main flow path 11. The flow rate sensor 114 measures the flow rate of the primary coolant flowing through the downstream part of the primary flow path 1, specifically, through a part of the primary flow path 1 downstream of the heat exchanger 3. The temperature sensor 115 is provided downstream of the flow rate sensor 114 in the main flow path 11, and measures the temperature of the primary coolant flowing through the downstream part of the primary flow path 1. The pressure sensor 116 is provided downstream of the temperature sensor 115 in the main flow path 11, and measures the pressure of the primary coolant flowing through the downstream part of the primary flow path 1.

The secondary flow path 2 is a flow path connecting the secondary inlet 92A and the secondary outlet 92B provided in the housing 9. The secondary inlet 92A and the secondary outlet 92B are open in the rear surface 91 of the housing 9.

The secondary flow path 2 includes a main flow path 21, a supply flow path 22, a first flow path 23, a second flow path 24, and a third flow path 25. The secondary coolant flows into the main flow path 21 from the secondary inlet 92A. Then, the stream in the main flow path 21 is separated into streams flowing through the first flow path 23, the second flow path 24, and the third flow path 25, and then these streams are merged into a stream in the main flow path 21, which flows out from the secondary outlet 92B.

In the main flow path 21, the pressure sensor 211, the temperature sensor 212, the heat exchanger 3, a flow rate sensor 213, the temperature sensor 214, and the pressure sensor 215 are provided in order from the upstream side.

The pressure sensor 211 measures the pressure of the secondary coolant flowing through the upstream part of the secondary flow path 2, specifically, through a part of the secondary flow path 2 upstream of the heat exchanger 3. The temperature sensor 212 is provided downstream of the pressure sensor 211 in the main flow path 21, and measures the temperature of the secondary coolant flowing through the upstream part of the secondary flow path 2.

The heat exchanger 3 is provided downstream of the temperature sensor 212 in the main flow path 21.

The supply flow path 22 is connected with the main flow path 21 at a position downstream of the heat exchanger 3 in the main flow path 21 and upstream of the junction of the first flow path 23 and the second flow path 24. The supply flow path 22 is connected to the tank 5.

At a position downstream of the junction of the main flow path 21 and the supply flow path 22, the main flow path 21 branches into the first flow path 23 and the second flow path 24. In the first flow path 23, a pump 231 and a check valve 232 are provided in order from the upstream side.

The pump 231 pumps the secondary coolant to the downstream side of the first flow path 23. The check valve 232 is provided downstream of the pump 231 in the first flow path 23, and prevents a backflow of the secondary coolant flowing through the secondary flow path 2.

In the second flow path 24, a pump 241 and a check valve 242 are provided in order from the upstream side.

The pump 241 pumps the secondary coolant to the downstream side of the second flow path 24. The check valve 242 is provided downstream of the pump 241 in the second flow path 24, and prevents a backflow of the secondary coolant flowing through the secondary flow path 2.

At a position downstream of the junction of the first flow path 23 and the second flow path 24, the third flow path 25 branches from the second flow path 24. In the third flow path 25, a pump 251 and a check valve 252 are provided in order from the upstream side.

The pump 251 pumps the secondary coolant to the downstream side of the third flow path 25. The check valve 252 is provided downstream of the pump 251 in the third flow path 25, and prevents backflow of the secondary coolant flowing through the secondary flow path 2.

The third flow path 25 is connected with the second flow path 24 at a position downstream of the check valve 242 and downstream of the check valve 252. The first flow path 23 and the second flow path 24 are connected to each other and to the main flow path 21, at the downstream ends of the first flow path 23 and the second flow path 24, that is, at a position downstream of the check valve 232 and downstream of the junction of the second flow path 24 and the third flow path 25.

The flow rate sensor 213 is provided downstream of the heat exchanger 3 in the main flow path 21. The flow rate sensor 213 measures the flow rate of the secondary coolant flowing through the downstream part of the secondary flow path 2, specifically, through a part of the secondary flow path 2 downstream of the heat exchanger 3. The flow rate sensor 213 is provided downstream of the pumps 231, 241, and 251 in the secondary flow path 2, and measures the flow rate of the secondary coolant flowing through a part of the secondary flow path 2 downstream of the pumps 231, 241, and 251. The temperature sensor 214 is provided downstream of the flow rate sensor 213 in the main flow path 21, and measures the temperature of the secondary coolant flowing through the downstream part of the secondary flow path 2. The pressure sensor 215 is provided downstream of the temperature sensor 214 in the main flow path 21, and measures the pressure of the secondary coolant flowing through the downstream part of the secondary flow path 2.

In the CDU 100 configured as described above, the pipes connected to the primary inlet 91A and the primary outlet 91B may be fixed by a clamp or the like. In such a case, if there is no path that branches from the primary flow path 1 and is provided for emitting the primary coolant to the outside of the housing 9, removal of the clamp may result in leakage of the primary coolant in the primary flow path 1, from the primary inlet 91A or the primary outlet 91B to the outside of the CDU 100.

Therefore, the CDU 100 according to the example embodiment includes the emission path 12 branching from the main flow path 11 of the primary flow path 1. The emission path 12 connects the emission port 10 provided in the housing 9 and the primary flow path 1.

This configuration makes it possible to emit, when the clamp for secure connection with an external flow path pipe is removed, the primary coolant through the emission path 12, and thus to suppress leakage of the primary coolant from the primary inlet 91A and the primary outlet 91B. In addition, this configuration also makes it possible to depressurize, when the internal pressure in the primary flow path 1 is high, the inside of the primary flow path 1 by emitting a part of the primary coolant in the CDU 100 through the emission path 12, and thus suppress jetting of the primary coolant from the primary inlet 91A and the primary outlet 91B.

As the emission path 12, a first emission path 121 and a second emission path 122 may be included. As the emission port 10, a first emission port 101 and a second emission port 102 may be included.

The first emission path 121 connects the first emission port 101 and the primary flow path 1. The first emission path 121 branches at a position between the primary inlet 91A and the heat exchanger 3 in the primary flow path 1, and communicates with the first emission port 101. Specifically, the first emission path 121 branches from the main flow path 11 at a position downstream of the pressure sensor 111 and upstream of the temperature sensor 112.

The second emission path 122 connects the second emission port 102 and the primary flow path 1. The second emission path 122 branches at a position between the heat exchanger 3 and the primary outlet 91B in the primary flow path 1, and communicates with the second emission port 102. Specifically, the second emission path 122 branches from the main flow path 11 at a position downstream of the temperature sensor 115 and upstream of the pressure sensor 116.

As described above, the CDU 100 according to the example embodiment includes the first emission path 121 and the second emission path 122, and thus, can more reliably emit the primary coolant in the primary flow path 1 and suppress leakage of the primary coolant from the primary inlet 91A and the primary outlet 91B, as compared with a case of including one of the first emission path 121 and the second emission path 122. Further, in contrast to a case where an emission path is provided on one of the upstream side and the downstream side of the heat exchanger 3 in the primary flow path 1, the primary coolant can be emitted without passing through the heat exchanger 3 having a high flow path resistance.

The primary inlet 91A, the primary outlet 91B, and the emission port 10 may be provided on the same face of the housing 9. In the example illustrated in FIGS. 3 and 4, the primary inlet 91A, the primary outlet 91B, the first emission port 101, and the second emission port 102 are provided in the rear surface 91 of the housing 9. For example, the rear surface 91 includes six openings penetrating in the X-axis direction. From each of the six openings, a tubular member with an axis extending along the X-axis direction protrudes from the rear surface 91 to one side in the X-axis direction (the positive side in the X-axis direction). In the housing 9, the six tubular members protruding from the rear surface 91 to one side in the X-axis direction are the primary inlet 91A, the primary outlet 91B, the secondary inlet 92A, the secondary outlet 92B, the first emission port 101, and the second emission port 102. The first emission port 101 and the second emission port 102 may be, for example, drain cups. The first emission port 101 and the second emission port 102 may be opened during emission operation through the emission path 12 when the clamp is removed.

Providing the primary inlet 91A, the primary outlet 91B, and the emission port 10 on the same face of the housing 9, as described above, facilitates emission operation through the emission path 12 when the clamp is removed, as compared to a case where the primary inlet 91A, the primary outlet 91B, and the emission port 10 are provided on different faces of the housing 9.

The distance between the first emission port 101 and the bottom face 96 of the housing 9 may be shorter than the distance between the primary inlet 91A and the bottom face 96, and the distance between the primary outlet 91B and the bottom face 96. Specifically, as illustrated in FIG. 4, a distance d1 in the Z-axis direction between the center position of the first emission port 101 and the bottom face 96 of the housing 9 may be shorter than a distance d2 in the Z-axis direction between the center position of the primary inlet 91A and the bottom face 96 of the housing 9. In addition, the distance d1 may be shorter than a distance d3 in the Z-axis direction between the center position of the primary outlet 91B and the bottom face 96 of the housing 9.

Similarly, the distance between the second emission port 102 and the bottom face 96 may be shorter than the distance between the primary inlet 91A and the bottom face 96, and the distance between the primary outlet 91B and the bottom face 96. Specifically, as illustrated in FIG. 4, a distance d4 in the Z-axis direction between the center position of the second emission port 102 and the bottom face 96 of the housing 9 may be shorter than the distance d2 in the Z-axis direction between the center position of the primary inlet 91A and the bottom face 96 of the housing 9. In addition, the distance d4 may be shorter than the distance d3 in the Z-axis direction between the center position of the primary outlet 91B and the bottom face 96 of the housing 9.

In other words, the first emission port 101 and the second emission port 102 may be located at vertically lower positions, as compared to the primary inlet 91A and the primary outlet 91B.

In this configuration in which the distance between the emission port 10 and the bottom face 96 is shorter than the distance between the primary inlet 91A and the bottom face 96, and the distance between the primary outlet 91B and the bottom face 96, the primary coolant can be easily collected from the first emission port 101 and the second emission port 102 during emission operation when the clamp is removed, as compared with the case where the first emission port 101 and the second emission port 102 are located at vertically higher positions than the primary inlet 91A and the primary outlet 91B.

The emission path 12 may be inclined vertically downward from the junction of the emission path 12 and the primary flow path 1 toward the emission port 10. This inclination prevents the coolant from remaining at the lower part of the flow path pipe of the primary flow path 1 or in the emission path 12, and facilitates emission of the primary coolant from the emission port 10.

The emission path 12 may be connected to the vertically lower side of the primary flow path 1. This prevents the coolant from remaining at the lower part of the flow path pipe of the primary flow path 1, and facilitates emission of the primary coolant from the emission port 10.

As illustrated in FIG. 3, the pressure sensor 111 and the pressure sensor 116 may be located in the vicinity of the emission port 10. Specifically, the pressure sensor 111 may be located in the vicinity of the first emission port 101. The pressure sensor 111 may be located upstream of the heat exchanger 3 in the primary flow path 1. The pressure sensor 111 may be located between the temperature sensor 112 and the primary inlet 91A in the primary flow path 1.

Similarly, the pressure sensor 116 may be located in the vicinity of the second emission port 102. The pressure sensor 116 may be located downstream of the heat exchanger 3 in the primary flow path 1. The pressure sensor 116 may be located between the temperature sensor 115 and the primary outlet 91B in the primary flow path 1.

Providing the pressure sensor 111 and the pressure sensor 116 in the vicinity of the emission ports 10, as described above, makes it possible to know the amount of pressure reduction due to emission of the primary coolant in the primary flow path 1 through the emission path 12.

The pressure sensor 111 is provided in the vicinity of the primary inlet 91A, and the pressure sensor 116 is provided in the vicinity of the primary outlet 91B. This makes it possible to early detect, based on detection of a change in the differential pressure between the pressure sensor 111 and the pressure sensor 116, an abnormality in the primary flow path 1, for example, clogging in the primary flow path 1. Specifically, if the differential pressure exceeds a threshold, the control unit 6 may provide a notice of an error using the display operation unit 8.

The control unit 6 may determine whether the primary flow path 1 is clogged by comparing the pressure in a normal state, that is, when there is no abnormality in the primary flow path 1, with measured values of the pressure sensors 111 and 116.

Note that, although the example in which the pressure sensors 111 and 116 are located in the vicinity of the emission ports 10 has been described here, the sensor to be provided in the vicinity of the emission port 10 is not limited to the pressure sensors 111 and 116. For example, a flow rate sensor may be located in the vicinity of the emission port 10. This makes it possible to know a change in the flow rate due to emission of the primary coolant in the primary flow path 1 through the emission path 12.

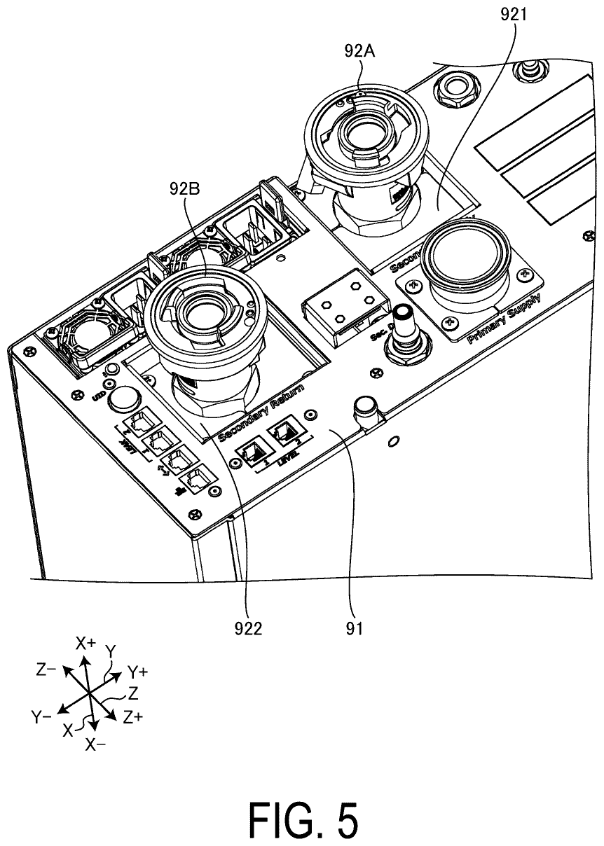

Next, the secondary inlet 92A and the secondary outlet 92B according to the example embodiment will be described with reference to FIG. 5. FIG. 5 is a perspective view illustrating the rear surface 91 of the CDU 100 according to the example embodiment.

As illustrated in FIG. 5, the rear surface 91 may have recesses in regions where the secondary inlet 92A and the secondary outlet 92B are provided. Specifically, the rear surface 91 may have a recess 921 in the region where the secondary inlet 92A is provided. Similarly, the rear surface 91 may have a recess 922 in the region where the secondary outlet 92B is provided.

This configuration can reduce the width of the CDU 100 in the X-axis direction, as compared to the case where the rear surface 91 is entirely flat. Specifically, as illustrated in FIG. 5, the secondary inlet 92A and the secondary outlet 92B protrude more outward from the housing 9 than other members located on the rear surface 91 (for example, the primary inlet 91A or the primary outlet 91B). Therefore, forming the recesses in the regions where the secondary inlet 92A and the secondary outlet 92B are provided, can reduce the width of the CDU 100 in the X-axis direction.

Although the example in which the recesses are provided in the regions where the secondary inlet 92A and the secondary outlet 92B are provided has been described here, a region where the recess is to be provided is not limited thereto. For example, the rear surface 91 may have a recess in a region where the primary inlet 91A, the primary outlet 91B, or the emission port 10 (see FIG. 3) is provided.

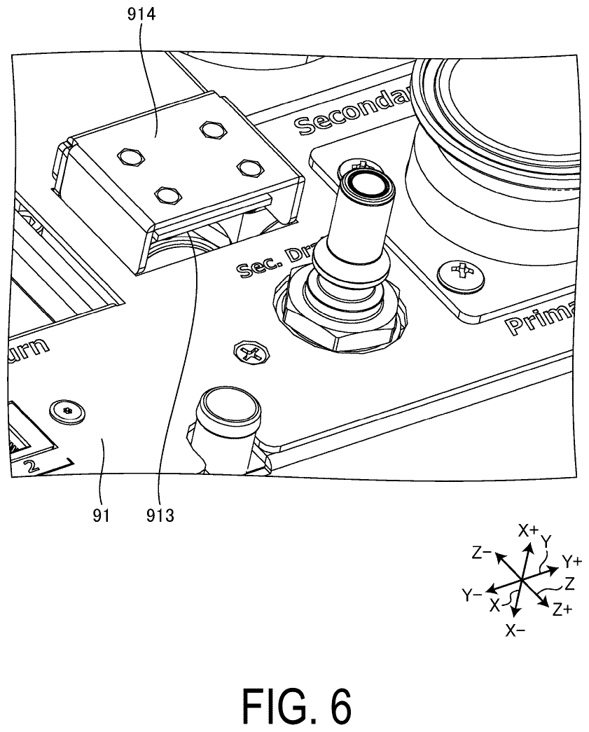

Next, a temperature and humidity sensor according to the example embodiment will be described with reference to FIG. 6. FIG. 6 is a perspective view illustrating the rear surface 91 of the CDU 100 according to the example embodiment.

As illustrated in FIG. 6, the CDU 100 may include a temperature and humidity sensor 913 located on the rear surface 91. This makes it possible to detect the temperature and the moisture in the vicinity of a pipe connected to the primary inlet 91A, the primary outlet 91B, the secondary inlet 92A, or the secondary outlet 92B, and thus facilitates maintenance of the pipe. Further, the temperature and humidity sensor 913 is disposed on the same face as the emission port 10, and thus the workability of emission operation when the clamp is removed is improved. The temperature and humidity sensor 913 may be covered with a cover member 914.

As described above, the CDU 100 according to the example embodiment includes the emission path 12 branching from the main flow path 11 of the primary flow path 1. The emission path 12 connects the emission port 10 provided in the housing 9 and the primary flow path 1. This configuration makes it possible to emit the primary coolant through the emission path 12, and thus to suppress leakage of the primary coolant from the primary inlet 91A and the primary outlet 91B.

Although the example in which the CDU 100 includes the two emission paths 12 branching from the primary flow path 1 has been described here, the number of emission paths 12 is not limited to two. The number of emission paths 12 may be one, or three or more.

### First Variation

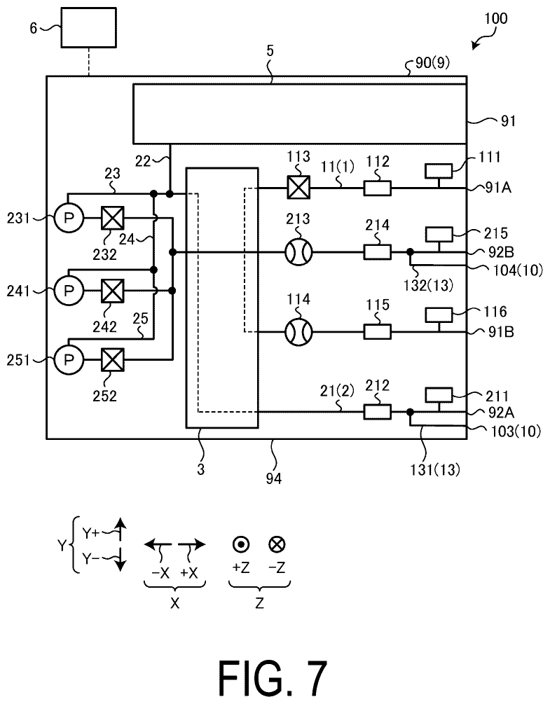

FIG. 7 is a diagram illustrating a simplified configuration of the CDU 100 according to a first variation. Although the example in which the CDU 100 includes the emission path 12 branching from the primary flow path 1 has been described in the above-described example embodiment, the CDU 100 may include an emission path 13 branching from the secondary flow path 2 as illustrated in FIG. 7. The emission path 13 connects the emission port 10 provided in the housing 9 and the secondary flow path 2.

As the emission path 13, a third emission path 131 and a fourth emission path 132 may be included. As the emission port 10, a third emission port 103 and a fourth emission port 104 may be included.

The third emission path 131 connects the third emission port 103 and the secondary flow path 2. The third emission path 131 branches at a position between the secondary inlet 92A and the heat exchanger 3 in the secondary flow path 2, and communicates with the third emission port 103. Specifically, the third emission path 131 branches from the main flow path 21 at a position downstream of the pressure sensor 211 and upstream of the temperature sensor 212.

The fourth emission path 132 connects the fourth emission port 104 and the secondary flow path 2. The fourth emission path 132 branches at a position between the heat exchanger 3 and the secondary outlet 92B in the secondary flow path 2, and communicates with the fourth emission port 104. Specifically, the fourth emission path 132 branches from the main flow path 21 at a position downstream of the temperature sensor 214 and upstream of the pressure sensor 215.

As described above, the CDU 100 including the emission path 13 branching from the secondary flow path 2 can emit the secondary coolant through the emission path 13 and suppress leakage of the secondary coolant from the secondary inlet 92A and the secondary outlet 92B. In particular, this configuration also makes it possible to depressurize, when the internal pressure in the secondary flow path 2 is high, the inside of the secondary flow path 2 by emitting a part of the secondary coolant through the emission paths 13, and thus suppress jetting of the secondary coolant from the secondary inlet 92A and the secondary outlet 92B.

The CDU 100 includes the third emission path 131 and the fourth emission path 132, and thus, can more reliably emit the secondary coolant in the secondary flow path 2 and suppress leakage of the secondary coolant from the secondary inlet 92A and the secondary outlet 92B, as compared with a case of including one of the third emission path 131 and the fourth emission path 132.

Although the example in which the CDU 100 includes the two emission paths 13 branching from the secondary flow path 2 has been described here, the number of emission paths 13 is not limited to two. The number of emission paths 13 may be one, or three or more.

### Second Variation

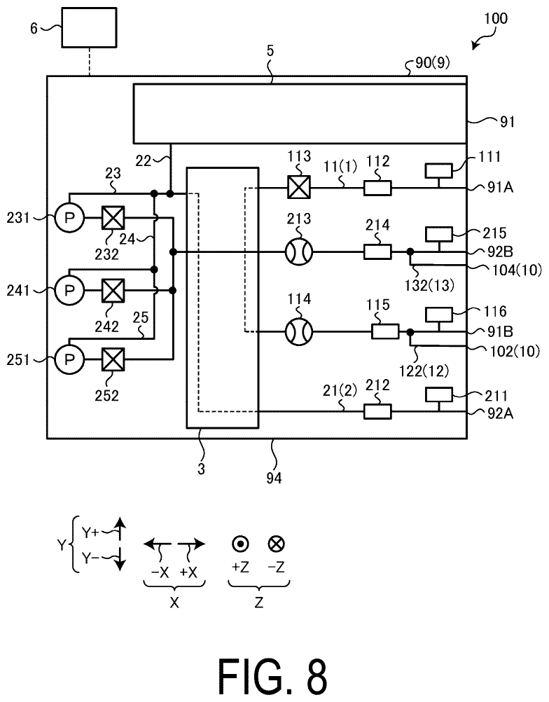

FIG. 8 is a diagram illustrating a simplified configuration of the CDU 100 according to a second variation. The example in which the CDU 100 includes the emission path 12 branching from the primary flow path 1 has been described in the above-described example embodiment and the example in which the CDU 100 includes the emission path 13 branching from the secondary flow path 2 has been described in the first variation. However, the CDU 100 may include both the emission path 12 and the emission path 13 as illustrated in FIG. 8.

In other words, the CDU 100 may include the two emission paths 122 and 132 and the two emission ports 102 and 104. The emission path 122 connects the emission port 102 and the primary flow path 1. The emission path 132 connects the emission port 104 and the secondary flow path 2.

As described above, the CDU 100 including the emission path 12 branching from the primary flow path 1 and the emission path 13 branching from the secondary flow path 2 can emit the primary coolant through the emission path 12 and can emit the secondary coolant through the emission path 13. As a result, leakage of the primary coolant from the primary inlet 91A and the primary outlet 91B and leakage of the secondary coolant from the secondary inlet 92A and the secondary outlet 92B are suppressed.

Although the example where the CDU 100 includes one emission path 12 branching from the primary flow path 1 and one emission path 13 branching from the secondary flow path 2 has been described above, the number of emission paths 12 and the number of emission paths 13 are not limited to one. For example, the CDU 100 may include two emission paths 12 and two emission paths 13. In this case, the two emission paths 12 may branch respectively from an upstream part and a downstream part of the primary flow path 1. Similarly, the two emission paths 13 may branch respectively from an upstream part and a downstream part of the secondary flow path 2. The CDU 100 may have emission ports respectively connected to the two emission paths 12 and the two emission paths 13.

### Third Variation

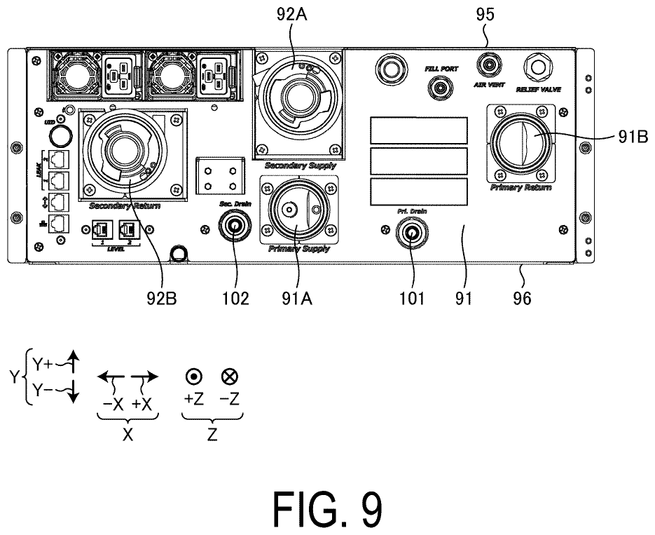

FIG. 9 is a schematic rear view of the CDU 100 according to a third variation.

The emission port 10 may be provided at a position offset from the primary inlet 91A and the primary outlet 91B in a direction (Y-axis direction) orthogonal to a direction of arrangement of the face 95 and the face 96. Specifically, as illustrated in FIG. 9, the first emission port 101 is provided at a position offset from the primary inlet 91A in the positive Y-axis direction. The first emission port 101 is provided at a position offset from the primary outlet 91B in the negative Y-axis direction. The second emission port 102 is provided at a position offset from the primary inlet 91A and the primary outlet 91B in the negative Y-axis direction.

Providing the emission port 10 at a position offset from the primary inlet 91A and the primary outlet 91B in the Y-axis direction, as described above, facilitates emission operation when the clamp is removed, as compared with a case where the emission port 10 is aligned with the primary inlet 91A and the primary outlet 91B in the Y-axis direction.

Although the example in which the emission port 10 is provided at a position offset from the primary inlet 91A and the primary outlet 91B in the Y-axis direction has been described here, this is merely an example. As described above in the first variation and the second variation, when the CDU 100 includes the emission path 13 branching from the secondary flow path 2, the emission port 10 communicating with the emission path 13 may be provided at a position offset from the secondary inlet 92A and the secondary outlet 92B in the Y-axis direction. This facilitates emission operation when the clamp is removed, as compared to a case where the emission port 10 is aligned with the secondary inlet 92A and the secondary outlet 92B in the Y-axis direction.

The emission port 10 may be provided between the primary inlet 91A and the primary outlet 91B in a direction of arrangement of two faces (here, the Y-axis direction) of the plurality of faces 91 to 94, which face each other. Specifically, as illustrated in FIG. 9, the first emission port 101 may be provided between the primary inlet 91A and the primary outlet 91B in the Y-axis direction.

This facilitates emission operation when the clamp is removed, because the primary inlet 91A, the primary outlet 91B, and the emission port 10 are located close to each other.

Although the example in which the first emission port 101 is provided between the primary inlet 91A and the primary outlet 91B has been described here, the second emission port 102 may also be provided between the primary inlet 91A and the primary outlet 91B. In a case where the CDU 100 includes the emission path 13 branching from the secondary flow path 2, as described above in the first variation example, the emission port 10 communicating with the emission path 13 may be provided between the secondary inlet 92A and the secondary outlet 92B in the Y-axis direction. This facilitates emission operation when the clamp is removed, because the secondary inlet 92A, the secondary outlet 92B, and the emission port 10 are located close to each other.

### Other Variations

The center axis of the flow path pipe of the emission path 12 may be located at a vertically lower position, as compared to the center axis of the flow path pipe of the primary flow path 1. This facilitates drainage from the primary flow path 1 through the emission path 12. Similarly, the center axis of the flow path pipe of the emission path 13 may be located at a vertically lower position, as compared to the center axis of the flow path pipe of the secondary flow path 2. This facilitates drainage from the secondary flow path 2 through the emission path 13.

The diameter of the flow path pipe of the emission path 12 may be smaller than the diameter of the flow path pipe of the primary flow path 1. This makes it possible to reduce the flow path loss of the primary flow path 1. Similarly, the diameter of the flow path pipe of the emission path 13 may be smaller than the diameter of the flow path pipe of the secondary flow path 2. This makes it possible to reduce the flow path loss of the secondary flow path 2.

A flow path pipe of the primary flow path 1 extending in an XY plane direction may be connected with a flow path pipe of the primary flow path 1 extending in the Z-axis direction and a flow path pipe of the emission path 12 extending in the Z-axis direction. Specifically, a flow path pipe of the primary flow path 1 may extend in an XY plane direction, and the flow path pipe may be formed in part by the flow path pipe of the primary flow path 1 described above. A flow path pipe of the primary flow path 1 may be connected to the emission path 12 in an XY plane direction.

Using the pipe members in this manner facilitates drainage of the emission path 12.

Similarly, a flow path pipe of the secondary flow path 2 extending in an XY plane direction may be connected with a flow path pipe of the secondary flow path 2 extending in the Z-axis direction and a flow path pipe of the emission path 13 extending in the Z-axis direction. This facilitates drainage of the emission path 13.

The present technology can also have the following configurations.

(1)

A coolant distribution unit including: a housing, a primary flow path being housed in the housing and connecting a primary inlet and a primary outlet, the primary inlet and the primary outlet being provided in the housing, a secondary flow path being housed in the housing and connecting a secondary inlet and a secondary outlet, the secondary inlet and the secondary outlet being provided in the housing, a heat exchanger housed in the housing and connected to the primary flow path and the secondary flow path, and at least one emission path being housed in the housing and connecting at least one emission port provided in the housing and the primary flow path or the secondary flow path.

(2)

The coolant distribution unit according to (1), in which the at least one emission path connects the at least one emission port and the primary flow path, and the primary inlet, the primary outlet, and the at least one emission port are provided on a same surface of the housing.

(3)

The coolant distribution unit according to (1) or (2), in which the at least one emission port includes a first emission port and a second emission port, and the at least one emission path includes a first emission path branching off at a position between the primary inlet and the heat exchanger in the primary flow path and communicating with the first emission port, and a second emission path branching off at a position between the heat exchanger and the primary outlet in the primary flow path and communicating with the second emission port.

(4)

The coolant distribution unit according to (2), in which the housing has a first surface located vertically below the heat exchanger, a second surface located opposite to the first surface, and a plurality of third surfaces connecting the first surface and the second surface, the primary inlet, the primary outlet, and the at least one emission port are located in the plurality of third surfaces, and a distance between the at least one emission port and the first surface is shorter than a distance between the primary inlet and the first surface and a distance between the primary outlet and the first surface.

(5)

The coolant distribution unit according to (2) or (4), in which the housing includes a first surface located vertically below the heat exchanger, a second surface located opposite to the first surface, and a plurality of third surfaces connecting the first surface and the second surface, the primary inlet, the primary outlet, and the at least one emission port are located in the plurality of third surfaces, and the at least one emission port is provided at a position offset from the primary inlet and the primary outlet in a direction orthogonal to or substantially orthogonal to a direction of arrangement of the first surface and the second surface.

(6)

The coolant distribution unit according to (2) or (4), in which the housing includes a first surface located vertically below the heat exchanger, a second surface located opposite to the first surface, and a plurality of third surfaces connecting the first surface and the second surface, the primary inlet, the primary outlet, and the at least one emission port are provided on the plurality of third surfaces, and the at least one emission port is provided between the primary inlet and the primary outlet in a direction of arrangement of two third surfaces opposing each other of the plurality of third surfaces.

(7)

The coolant distribution unit according to any one of (1) to (6), in which the at least one emission port includes a third emission port and a fourth emission port, and the at least one emission path includes at least one of a third emission path branching off at a position between the secondary inlet and the heat exchanger in the secondary flow path and communicating with the third emission port, or a fourth emission path branching off at a position between the heat exchanger and the secondary outlet in the secondary flow path and communicating with the fourth emission port.

(8)

The coolant distribution unit according to (1), in which the at least one emission path includes two emission paths and the at least one emission port includes two emission ports, and one of the two emission paths connects one of the two emission ports and the primary flow path, and another of the two emission paths connects the other of the two emission ports and the secondary flow path.

(9)

The coolant distribution unit according to any one of (1) to (8), further including a pressure sensor or a flow rate sensor located adjacent to the at least one emission port.

The example embodiments disclosed herein are to be considered in all respects as illustrative and not restrictive. Indeed, the above-described example embodiments may be embodied in a variety of forms. Furthermore, omission, replacement, or modification for the above-described example embodiments can be made in various forms without departing from the scope and spirit of the appended claims.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A coolant distribution unit, comprising:
a housing;
a primary flow path being housed in the housing and connecting a primary inlet and a primary outlet, the primary inlet and the primary outlet being provided in the housing;
a secondary flow path being housed in the housing and connecting a secondary inlet and a secondary outlet, the secondary inlet and the secondary outlet being provided in the housing;
a heat exchanger housed in the housing and connected to the primary flow path and the secondary flow path; and
at least one emission path being housed in the housing and connecting at least one emission port provided in the housing and the primary flow path or the secondary flow path.

2. The coolant distribution unit according to claim 1, wherein
the at least one emission path connects the at least one emission port and the primary flow path; and
the primary inlet, the primary outlet, and the at least one emission port are provided on a same surface of the housing.

3. The coolant distribution unit according to claim 1, wherein the at least one emission port includes a first emission port and a second emission port; and
the at least one emission path includes:
a first emission path branching off at a position between the primary inlet and the heat exchanger in the primary flow path and communicating with the first emission port; and
a second emission path branching off at a position between the heat exchanger and the primary outlet in the primary flow path and communicating with the second emission port.

4. The coolant distribution unit according to claim 2, wherein
the housing includes a first surface located vertically below the heat exchanger, a second surface located opposite to the first surface, and a plurality of third surfaces connecting the first surface and the second surface;
the primary inlet, the primary outlet, and the at least one emission port are located in the plurality of third surfaces; and
a distance between the at least one emission port and the first surface is shorter than a distance between the primary inlet and the first surface and a distance between the primary outlet and the first surface.

5. The coolant distribution unit according to claim 2, wherein
the housing includes a first surface located vertically below the heat exchanger, a second surface located opposite to the first surface, and a plurality of third surfaces connecting the first surface and the second surface;
the primary inlet, the primary outlet, and the at least one emission port are located in the plurality of third surfaces; and
the at least one emission port is provided at a position offset from the primary inlet and the primary outlet in a direction orthogonal or substantially orthogonal to a direction of arrangement of the first surface and the second surface.

6. The coolant distribution unit according to claim 2, wherein
the housing includes a first surface located vertically below the heat exchanger, a second surface located opposite to the first surface, and a plurality of third surfaces connecting the first surface and the second surface;
the primary inlet, the primary outlet, and the at least one emission port are provided on the plurality of third surfaces; and
the at least one emission port is provided between the primary inlet and the primary outlet in a direction of arrangement of two third surfaces opposing each other of the plurality of third surfaces.

7. The coolant distribution unit according to claim 1, wherein
the at least one emission port includes a third emission port and a fourth emission port; and
the at least one emission path includes at least one of:
a third emission path branching off at a position between the secondary inlet and the heat exchanger in the secondary flow path and communicating with the third emission port; or
a fourth emission path branching off at a position between the heat exchanger and the secondary outlet in the secondary flow path and communicating with the fourth emission port.

8. The coolant distribution unit according to claim 1, wherein
the at least one emission path includes two emission paths and the at least one emission port includes two emission ports; and
one of the two emission paths connects one of the two emission ports and the primary flow path, and another of the two emission paths connects the other of the two emission ports and the secondary flow path.

9. The coolant distribution unit according to claim 1, further comprising a pressure sensor or a flow rate sensor located adjacent to the at least one emission port.
